(19) United States
(12) Patent Application Publication
(10) Pub. No.: US 2026/0313831 A1
(43) Pub. Date: Oct. 8, 2026

(54) CHANNEL GEOMETRY FOR TARGETED ENHANCED COOLING IN COLD PLATES

(71) Applicant: Dell Products L.P., Round Rock, TX (US)

(72) Inventors: MEGAN CHERIE WINGFIELD, Dalzell, SC (US); EMILY B. CLARK, Round Rock, TX (US); ABIGAIL MARIE MEZA, Round Rock, TX (US)

(21) Appl. No.: 19/169,744

(22) Filed: Apr. 3, 2025

(51) Int. Cl. H05K 7/20

(52) U.S. Cl. CPC H05K 7/20254; H05K 7/20272

(57) ABSTRACT

Devices, systems, and methods for providing thermal management of data processing systems that provide computer implemented services are disclosed. To provide such services, a data processing system may include a first temperature sensitive component, a second temperature sensitive component, a chassis, and a cold plate. The cold plate may include a first region for cooling the first temperature sensitive component. The cold plate may also include a second region for cooling the second temperature sensitive component. The second region may be adapted to generate a mixed flow proximate to the second temperature component.

### FIELD

Embodiments disclosed herein relate generally to management of data processing systems. More particularly, embodiments disclosed herein relate to systems and methods for thermal management of a data processing system.

### BACKGROUND

Computing devices may provide computer-implemented services. The computer-implemented services may be used by users of the computing devices and/or devices operably connected to the computing devices. The computer-implemented services may be performed with hardware components such as processors, memory modules, storage devices, and communication devices. The operation of these components may impact the performance of the computer-implemented services.

### BRIEF DESCRIPTION OF THE DRAWINGS

Embodiments disclosed herein are illustrated by way of example and not limitation in the figures of the accompanying drawings in which like references indicate similar elements.

FIG. 1 shows a diagram illustrating a data processing system in accordance with an embodiment.

FIGS. 2A-2C show diagrams illustrating a thermal management system for components of a data processing system using a cold plate in accordance with an embodiment.

FIGS. 3A-3C show diagrams illustrating a cold plate in accordance with an embodiment.

FIGS. 4A-4D show coolant flow channels in accordance with an embodiment.

FIG. 5 shows a block diagram illustrating a data processing system in accordance with an embodiment.

### DETAILED DESCRIPTION

Various embodiments will be described with reference to details discussed below, and the accompanying drawings will illustrate the various embodiments. The following description and drawings are illustrative and are not to be construed as limiting. Numerous specific details are described to provide a thorough understanding of various embodiments. However, in certain instances, well-known or conventional details are not described in order to provide a concise discussion of embodiments disclosed herein.

Reference in the specification to “one embodiment” or “an embodiment” means that a particular feature, structure, or characteristic described in conjunction with the embodiment can be included in at least one embodiment. The appearances of the phrases “in one embodiment” and “an embodiment” in various places in the specification do not necessarily all refer to the same embodiment.

References to an “operable connection” or “operably connected” means that a particular device is able to communicate with one or more other devices. The devices themselves may be directly connected to one another or may be indirectly connected to one another through any number of intermediary devices, such as in a network topology.

In general, embodiments disclosed herein relate to methods, systems, and devices for managing operation of a data processing system. The data processing system may provide computer-implemented services.

To provide the computer-implemented services, the data processing system may include hardware components. Each hardware component may include various temperature sensitive components, which may each have a thermal dissipation requirement that must be met for the hardware component to operate nominally (e.g., with low probability of error, low chance of damage/failure, etc.). The thermal dissipation requirements may include, for example, an optimal temperature range, an optimal rate of cooling of the temperature sensitive component to maintain the temperature range, and/or other requirements.

To meet the thermal dissipation requirements of the temperature sensitive components, the data processing system may use a liquid cooling system. For example, the liquid cooling system may be implemented using a cold plate adapted to cool the temperature sensitive components using liquid coolant. To do so, the cold plate may receive a coolant flow via cooling tubes adapted to transport the coolant flow within a chassis of the data processing system. The coolant may perform heat exchange with the temperature sensitive components to meet the thermal dissipation requirements, and may be expelled from the cold plate.

However, the temperature sensitive components of a hardware component may have different thermal dissipation requirements. For example, the hardware component may include a first temperature sensitive component having a first thermal dissipation requirement, and a second temperature sensitive component having a second thermal dissipation requirement. The cold plate may be adapted to cool the first temperature sensitive component, and may, as a result, fail to meet the thermal dissipation requirement of the second temperature sensitive component.

To meet the thermal dissipation requirements of each of the temperature sensitive components, the cold plate may include various regions, and each region may be adapted to cool a temperature sensitive component using a rate of cooling that meets the thermal dissipation requirement of the temperature sensitive component. For example, the cold plate may include a first region for cooling the first temperature sensitive component having the first thermal dissipation requirement, and a second region for cooling the second temperature sensitive component having the second thermal dissipation requirement. The second region may be adapted to generate a mixed flow (e.g., a flow with enhanced heat transfer) proximate to the second temperature sensitive component to meet the second thermal dissipation requirement.

While described with respect to a first region of the cold plate for cooling the first temperature sensitive component and a second region of the cold plate for cooling the second temperature sensitive component, it will be appreciated that the cold plate may include any number of regions, may include any number of temperature sensitive components within each region, and/or the regions may be cooled in any order sequentially and/or simultaneously.

To meet the thermal dissipation requirements, the cold plate may include: (i) a first coolant flow channel positioned in the first region and adapted to thermally manage the first temperature sensitive component, and (ii) a second coolant flow channel positioned in the second region and adapted to thermally manage the second temperature sensitive component. The second coolant flow channel may be adapted to generate the mixed flow, and the first coolant flow channel may not be adapted to generate the mixed flow. As a result, a first rate of cooling of the first temperature sensitive component may be lower than a second rate of cooling of the second temperature sensitive component.

To generate the mixed flow, the second coolant flow channel may include: (i) a first portion adapted to define a coolant flow path, and (ii) a second portion adapted to generate the mixed flow. The second portion may include mixed flow generation elements, such as posts and/or flow-altering channel walls (e.g., channel walls with flow-altering geometries). The mixed flow generation elements may be adapted to cause intermixing of portions of the coolant flow through the second coolant flow channel, which may establish the mixed flow. Thus, the second temperature sensitive component may be cooled at a faster rate relative to the first temperature sensitive component, which may allow the first thermal dissipation requirement and the second thermal dissipation requirement to be met.

Thus, embodiments disclosed herein may provide an improved data processing system that may meet thermal dissipation requirements of temperature sensitive components of a hardware component using a cold plate. The cold plate may include various regions, and each region may be adapted to cool a temperature sensitive component at a rate which meets a thermal dissipation requirement of the temperature sensitive component. To do so, at least one of the various regions may include a coolant flow channel adapted to generate a mixed flow. Consequently, each temperature sensitive component of the hardware component may operate as desired, and computer-implemented services may be reliably provided by the data processing system using the hardware component.

In an embodiment, a data processing system is provided. The data processing system may include: a first temperature sensitive component having a first thermal dissipation requirement; a second temperature sensitive component having a second thermal dissipation requirement; a chassis for housing the first temperature sensitive component and the second temperature sensitive component; and a cold plate, including: a first region for cooling the first temperature sensitive component; and a second region for cooling the second temperature sensitive component, the second region being adapted to generate a mixed flow proximate to the second temperature sensitive component to meet the second thermal dissipation requirement.

The cold plate may also include: a first coolant flow channel that is: positioned in the first region, and adapted to thermally manage the first temperature sensitive component; and a second coolant flow channel that is: positioned in the second region, and adapted to thermally manage the second temperature sensitive component.

The cold plate may be adapted to: receive a coolant flow; divide the coolant flow into a first portion of the coolant flow using the first coolant flow channel, and a second portion of the coolant flow using the second coolant flow channel; and expel the coolant flow from the cold plate after the coolant flow traverses through the first region and the second region.

The second coolant flow channel may be adapted to generate the mixed flow using the second portion of the coolant flow, and the first coolant flow channel may not be adapted to generate the mixed flow.

The second coolant flow channel may include: a first portion of the second coolant flow channel adapted to: define a coolant flow path from a first side of the second region to a second side of the second region; and a second portion of the second coolant flow channel adapted to generate the mixed flow.

The second portion of the second coolant flow channel may include: posts positioned with respect to the first portion to direct the coolant flow path to intermix portions of the second portion of the coolant flow along a direction of travel of the second portion of the coolant flow, the intermixing of the portions establishing the mixed flow.

The second portion of the second coolant flow channel may include: flow-altering channel walls positioned with respect to the first portion to direct the coolant flow path to intermix portions of the second portion of the coolant flow along a direction of travel of the second portion of the coolant flow, the intermixing of the portions establishing the mixed flow.

The second portion of the second coolant flow channel may be adapted to cause intermixing of portions of the second portion of the coolant flow to increase a rate of cooling so that a likelihood of the second thermal dissipation requirement being met is improved.

A first rate of cooling of the first temperature sensitive component may be lower than a second rate of cooling of the second temperature sensitive component.

The first rate of cooling may be adapted to meet the first thermal dissipation requirement, and the second rate of cooling may be adapted to meet the second thermal dissipation requirement.

The mixed flow may have a serpentine flow pattern.

In an embodiment, a chassis that may include a cold plate is provided.

In an embodiment, a cold plate for use with a data processing system is provided.

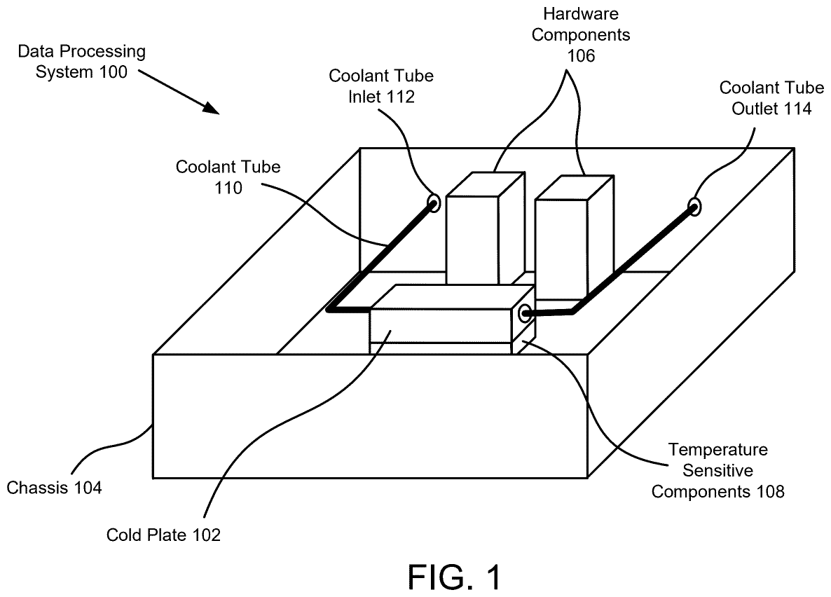

Turning to FIG. 1, a diagram illustrating a system in accordance with an embodiment is shown. The system shown in FIG. 1 may provide any quantity and type of computer-implemented services. To provide the computer-implemented services, the system of FIG. 1 may include data processing system 100.

Data processing system 100 may include functionality to provide various types of computer-implemented services. The computer-implemented services may include any number and type of computer-implemented services. The computer-implemented services may include, for example, database services, data processing services, electronic communication services, and/or any other services that may be provided using one or more computing devices. Other types of computer-implemented services may be provided by data processing system 100 without departing from embodiments disclosed herein.

To provide the computer-implemented services, various components of data processing system 100 may be positioned inside of a chassis (e.g., chassis 104). Chassis 104 may be a physical enclosure for housing components of data processing system 100, such as hardware components 106. Hardware components 106 may include any type and quantity of hardware components such as processors, memory modules, storage devices, communications devices, and/or other types of devices.

The components of data processing system 100 housed by chassis 104 may also include temperature sensitive components 108. Temperature sensitive components 108 may include any number and/or type of hardware components of data processing system 100 which may have thermal dissipation requirements. For example, to provide their functionalities, temperature sensitive components 108 may consume power (e.g., electricity) and generate heat as a byproduct of operations performed using the power. Any of temperature sensitive components 108 may have thermal dissipation requirements including, for example, a nominal operating thermal range (e.g., the components may not operate as desired outside of the nominal range), a rate of cooling to maintain the nominal temperature range, etc. Generation of the heat may change temperatures of temperature sensitive components 108 that, if not managed, may cause the temperatures of temperature sensitive components 108 to fall outside of the nominal range. Consequently, the heat generated by temperature sensitive components 108 may prevent the computer-implemented services from being provided as desired if the heat is not managed properly.

In general, embodiments disclosed herein may provide methods, systems, and/or devices for improving a likelihood that data processing system 100 is able to provide its computer-implemented services. To improve the likelihood that data processing system 100 is able to provide its computer-implemented services, data processing system 100 may include functionality to cool temperature sensitive hardware components that are internal to data processing system 100 and integral to the performance of the computer-implemented services (e.g., temperature sensitive components 108) using a cold plate (e.g., cold plate 102). The cold plate may be used to cool temperature sensitive hardware components 108 at a rate which meets thermal dissipation requirements (e.g., through thermal exchange) of each of temperature sensitive components 108, which may differ by component.

To do so, cold plate 102 may include a region adapted to generate a mixed flow proximate to a temperature sensitive component. To generate the mixed flow, the region may include a coolant flow channel, which may include mixed flow generation elements adapted to cause intermixing of portions of a coolant flow (e.g., posts, flow-altering channel walls, etc.). The mixed flow may increase a rate of cooling of the temperature sensitive component (e.g., relative to a flow that is not mixed), which may improve a likelihood of meeting the thermal dissipation requirement of the temperature sensitive component. By doing so, the temperature sensitive component may perform its functionality as desired, and the computer-implemented services may be provided by data processing system 100.

To provide the above noted functionality, data processing system 100 may include cold plate 102, chassis 104, hardware components 106, temperature sensitive components 108, coolant tube 110, coolant tube inlet 112, and/or coolant tube outlet 114. Each of these components is discussed below.

Any of the components of data processing system 100 may be positioned in chassis 104. Chassis 104 may include an enclosure in which physical structures of cold plate 102, hardware components 106, temperature sensitive components 108, coolant tube 110, coolant tube inlet 112, coolant tube outlet 114, and/or other components may be positioned. For example, chassis 104 may facilitate placement and management of hardware components 106 and/or other components in a computing environment.

For example, chassis 104 may house hardware components 106. Hardware components 106, as discussed above, may include any type and quantity of hardware components such as processors, memory modules, storage devices, communications devices, and/or other types of devices used to provide computer-implemented services. Hardware components 106 may also include power (e.g., power supplies) and/or thermal components, such as cooling fans, heatsinks, and/or other components used as part of an air cooling system.

The thermal components included as part of hardware components 106 (e.g., cooling fans, heatsinks) may contribute to thermal management of a portion of components of data processing system 100. For example, the heatsinks may increase surface area of the portion of the components and the cooling fans may direct air flow across the increased surface area, allowing for heat dissipation.

However, in some case, air cooling may be insufficient (e.g., air cooling may be unable to maintain the nominal temperature range), inefficient (e.g., powering the components used to provide the air cooling may consume an undesirable amount of power), and/or impractical (e.g., due to spatial limitations of chassis 104) to cool various components, such as temperature sensitive components 108. Temperature sensitive components 108 may include any number, type, and/or portion of hardware components which have thermal dissipation requirements.

For example, data processing system 100 may include a graphics processing unit (GPU). The GPU may include various temperature sensitive components (e.g., temperature sensitive components 108), including: (i) a first temperature sensitive component, and (ii) a second temperature sensitive component. The GPU may be capable of performing a high capacity of functionalities for data processing system 100 and may perform any number of these functionalities within a short amount of time. As a result, the various temperature sensitive components of the GPU may generate heat.

The various temperature sensitive components may each have a thermal dissipation requirement to maintain desired operation. For example, the first temperature sensitive component may have a first thermal dissipation requirement, and the second temperature sensitive component, may have a second thermal dissipation requirement. The thermal dissipation requirements may include a nominal temperature range for each temperature sensitive component to allow for desired operation. To dissipate the heat generated during operation to meet the thermal dissipation requirements, a liquid cooling system may be used (e.g., in addition to and/or in place of an air cooling system).

The heat generated during operation may differ for each temperature sensitive component of the GPU. For example, the second temperature sensitive component may generate more heat than the first temperature sensitive component. As a result, the liquid cooling system may be sufficiently cool the first temperature sensitive component, and may at least partially fail to meet the second thermal dissipation requirement.

To improve a likelihood that the thermal dissipation requirements for each of temperature sensitive components 108 are met, the system may include cold plate 102, coolant tube 110, coolant tube inlet 112, and/or coolant tube outlet 114. Each of these components are described below.

Coolant tube 110 may include flexible and/or rigid tubing adapted to transport a flow of liquid coolant within chassis 104 to participate in thermal management of temperature sensitive components 108. For example, coolant tube 110 may be part of a liquid cooling system (e.g., a direct liquid cooling system) in which coolant is circulated through cold plate 102. To do so, the coolant may enter chassis 104 via coolant tube inlet 112 and may exit chassis 104 via coolant tube outlet 114. Coolant tube inlet 112 and coolant tube outlet 114 may include openings in chassis 104 adapted to allow coolant tube 110 to be at least partially positioned within chassis 104. Other components (not shown) may also be used to facilitate performance of liquid-based cooling of temperature sensitive components 108, such as coolant reservoirs, chillers, coolant circulation pumps, and/or other components.

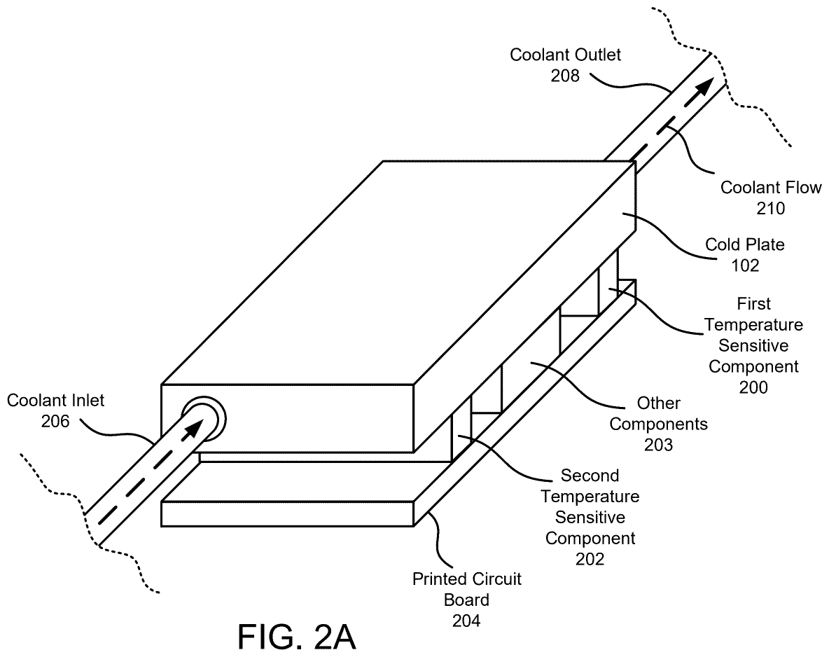

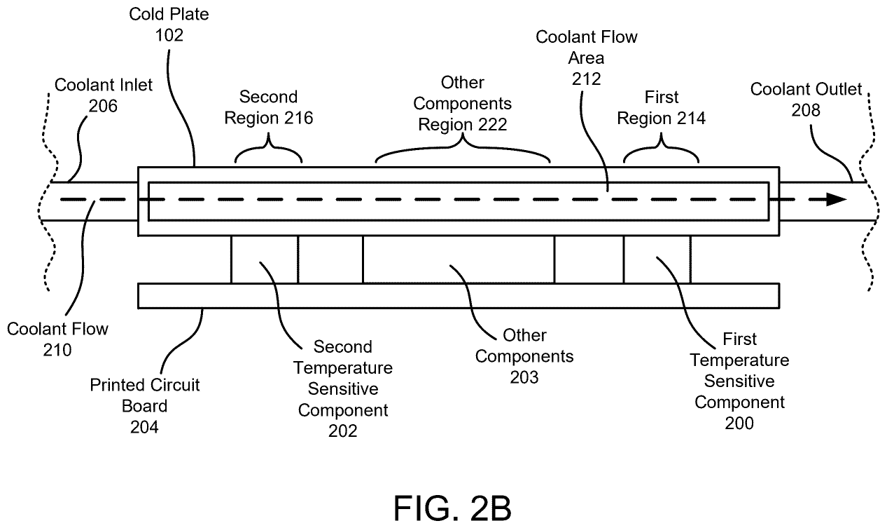

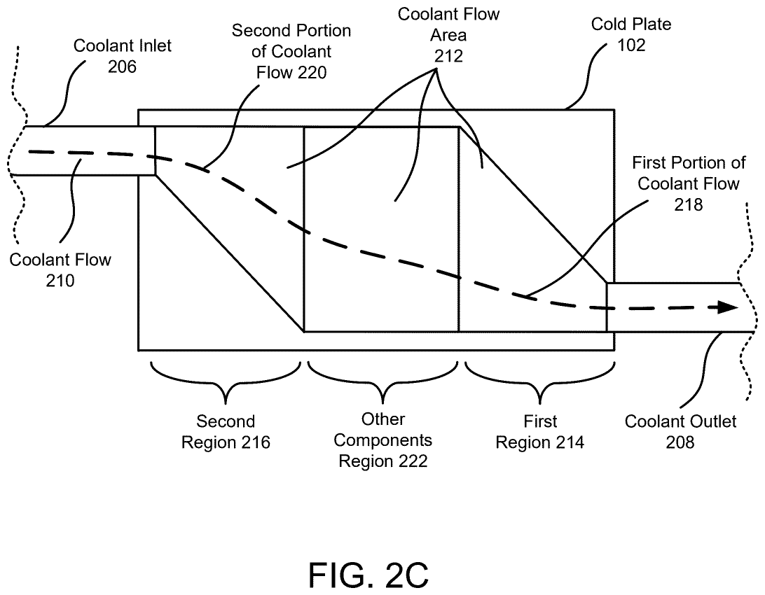

Coolant tube 110 may provide the coolant to cold plate 102 to thermally manage temperature sensitive components 108. Cold plate 102 may be positioned with (e.g., may be in thermal contact with) temperature sensitive components 108, and may receive the coolant circulated by coolant tube 110. The coolant, while traversing cold plate 102, may absorb heat from temperature sensitive components 108. The coolant may circulate through a loop (e.g., via coolant tube inlet 112 and coolant tube outlet 114), and be cooled by a heat exchanger (not shown). Cold plate 102 may include a plurality of regions, and each region may be adapted to cool each of temperature sensitive components 108 in a manner that meets each of the thermal dissipation requirements. For example, a first region of cold plate 102 may adapted to meet a first thermal dissipation requirement for a first temperature sensitive component, and a second region of cold plate 102 may be adapted to meet a second thermal dissipation requirement of a second temperature sensitive component. Refer to the description of FIGS. 2A-2B for additional details.

While described as being part of data processing system 100, it will be appreciated that any of the components used to provide the liquid-based cooling may be positioned and/or otherwise be distinct from data processing system 100.

While illustrated in FIG. 1 with a limited number of specific components, a system may include additional, fewer, and/or different components without departing from embodiments disclosed herein.

Turning to FIGS. 2A-2C, diagrams illustrating a thermal management system for components of a data processing system (e.g., data processing system 100) using a cold plate in accordance with an embodiment are shown. In FIG. 2A, the thermal management system may be illustrated using an isometric view diagram, in FIG. 2B the thermal management system may be illustrated using a side view diagram, and in FIG. 2C the thermal management system may be illustrated using a top view diagram. FIGS. 2B-2C may show the cold plate in a partially cutaway view.

As discussed above, data processing system 100 may include temperature sensitive components. The temperature sensitive components may include, for example: (i) first temperature sensitive component 200, (ii) second temperature sensitive component 202, and/or (iii) other components 203. Each of the temperature sensitive components may be positioned on printed circuit board 204, which may include a platform for mounting and operably connecting hardware components (and/or portions thereof) to generate a circuit. Printed circuit board 204 may be of any size, shape, or thickness to allow for the operable connection of the components.

First temperature sensitive component 200, second temperature sensitive component 202, and other components 203 may be hardware components and/or portions of hardware components. For example, first temperature sensitive component 200 may include a first portion of a hardware component, second temperature sensitive component 202 may include a second portion of the hardware component, and other components 203 may include a third portion of the hardware component. The hardware component may also include other portions (not shown).

For example, the hardware components of data processing system 100 may include a graphics processing unit (GPU). The GPU may include a first temperature sensitive component, for example a voltage regulator module, and a second temperature sensitive component, for example a video memory. The GPU may also include other components (e.g., other components 203), such as a main die (e.g., a silicon chip that performs graphics processing functions). The GPU may also include other components without departing from embodiments disclosed herein.

First temperature sensitive component 200, second temperature sensitive component 202, and/or other components 203 may generate heat during operation, and an amount of heat generated may vary by component. For example, other components 203 may generate the most heat of the components. As a result, a cooling system may be designed to cool other components 203. However, first temperature sensitive component 200 and second temperature sensitive component 202 may also generate heat, which may require and/or operation may be improved by cooling.

Each of the portions of the hardware component may have a thermal dissipation requirement. For example, first temperature sensitive component 200 may have a first thermal dissipation requirement, and second temperature sensitive component 202 may have a second thermal dissipation requirement. The thermal dissipation requirements may indicate: (i) a nominal temperature range for desired operation, (ii) cooling requirements to maintain the nominal temperature range, such as a rate of cooling (e.g., using a liquid cooling system, air cooling system, or both), and/or (iii) other requirements for operation.

As a result of the varying amounts of heat generated by each component, the thermal dissipation requirements for each component may differ. For example, the thermal dissipation requirements may indicate a rate of cooling for each component. If first temperature sensitive component 200 generates less heat than second temperature component 202 (and/or for any other reason), a first rate of cooling indicated by the first thermal dissipation requirement may be lower than a second rate of cooling indicated by the second thermal dissipation requirement.

Returning to the above example, the voltage regulator module (e.g., the first temperature sensitive component) may generate less heat than the video memory (e.g., the second temperature sensitive component) during operation of the GPU. A first thermal dissipation requirement for the voltage regulator module and a second thermal dissipation requirement for the video memory may indicate a nominal temperature range for operation of 30-40° C. To maintain temperatures compliant with the nominal temperature range, a rate of cooling indicated by the first thermal dissipation requirement for the voltage regulator module may be lower than a rate of cooling indicated by the second dissipation requirement for the video memory.

To meet the thermal dissipation requirements for each of the temperature sensitive components, the system may include, as discussed above, cold plate 102. Cold plate 102 may be used as part of a liquid cooling system. Cold plate 102 may include: (i) a first region for cooling first temperature sensitive component 200 (e.g., first region 214), (ii) a second region for cooling second temperature sensitive component 202 (e.g., second region 216), and/or (iii) other components region 222 for cooling other components 203.

First region 214 may be positioned with respect to first temperature sensitive component 200. For example, first region 214 may include a portion of cold plate 102 positioned above first temperature sensitive component 200. While illustrated as regions of cold plate 102 being positioned above the temperature sensitive components, it will be appreciated that the regions may be positioned below, to the side of, and/or in any other orientation with respect to the temperature sensitive components.

To cool the temperature sensitive components, cold plate 102 may receive a coolant flow (e.g., coolant flow 210). Coolant flow 210 may include a flow of any volume, flow rate, and/or type of coolant, such as water, ethylene glycol, etc. Coolant flow 210 may circulate through a loop through cold plate 102, and be cooled by a cooling component such as a heat exchanger (not shown).

To receive coolant flow 210, cold plate 102 may include coolant inlet 206. Coolant inlet 206 may enable coolant flow 210 to enter cold plate 102. Coolant inlet 206 may include a coolant tube and an opening through an exterior wall of cold plate 102. The coolant tube and/or opening may be of any size and/or shape through which coolant flow 210 may enter cold plate 102. For example, coolant inlet 206 may be rectangular, circular, and/or any other shape.

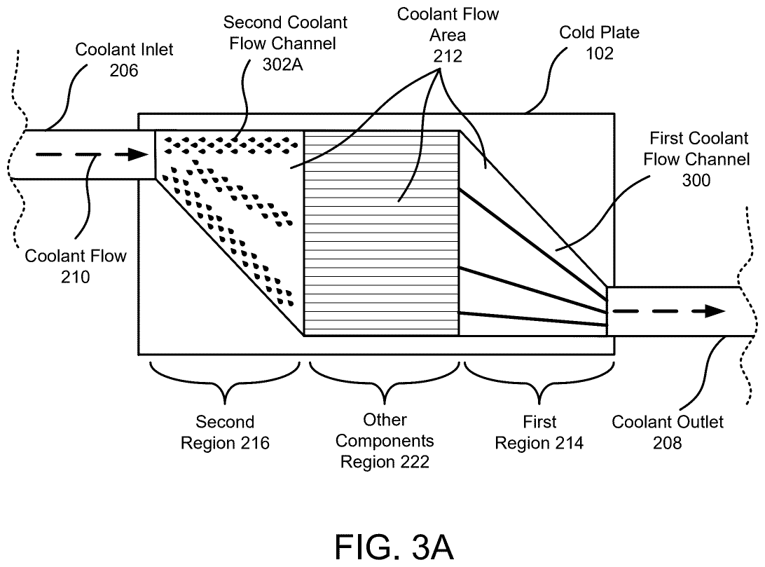

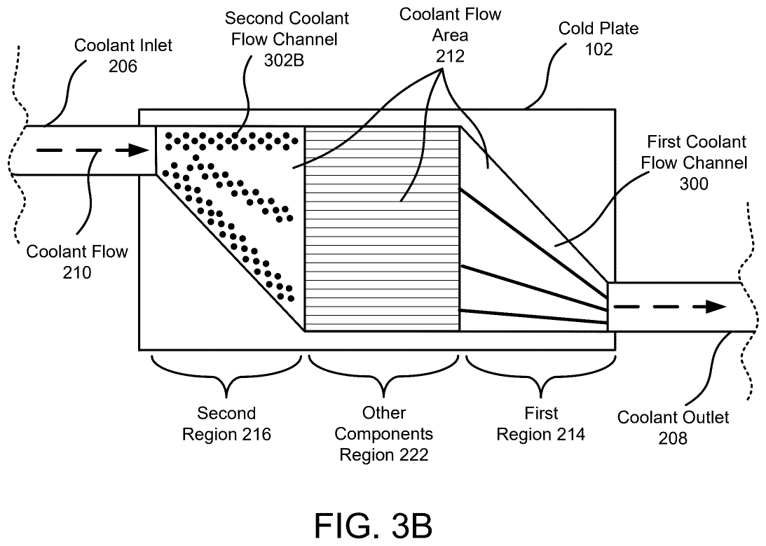

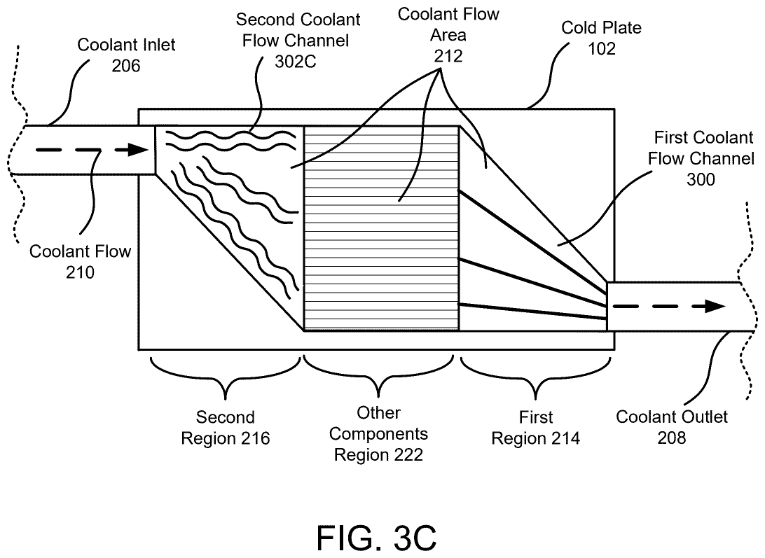

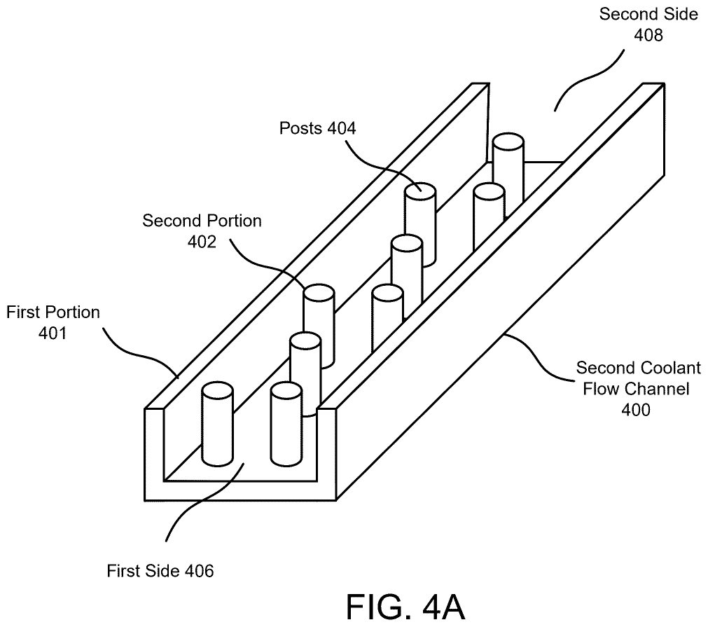

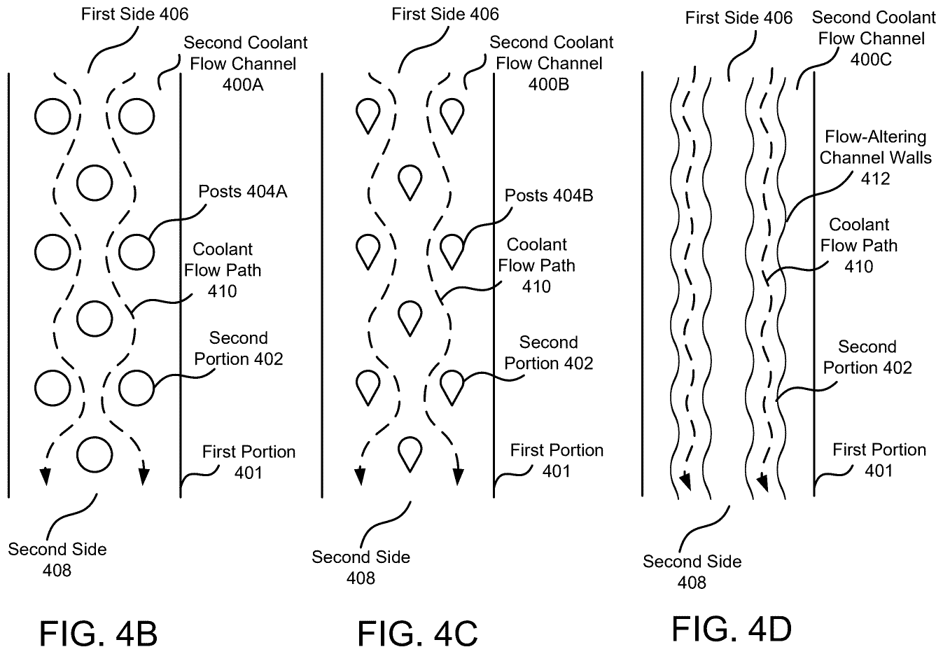

The coolant may be received by cold plate 102 into coolant flow area 212. Coolant flow area 212 may include an interior volume of cold plate 102. For example, cold plate 102 may include a shell, walls, and/or other structures arranged to enclose an interior volume through which coolant flow 210 may traverse. Coolant flow area 212 may include coolant flow channels adapted to divide coolant flow 210 into portions, and the portions may be associated with various regions of cold plate 102. Coolant flow 210 may then traverse through the various regions. For additional details regarding the coolant flow channels, refer to the description of FIGS. 3A-4D.

For example, coolant flow 210 may be divided (e.g., via coolant flow channels, not shown) into first portion of coolant flow 218 and second portion of coolant flow 220 (as shown in FIG. 2C). First portion of coolant flow 218 may be a portion of coolant flow 210 which traverses through first region 214, and second portion of coolant flow 220 may be a portion of coolant flow 210 which traverses through second region 216. In doing so, first portion of coolant flow 218 may be used to cool first temperature sensitive component 200, and second portion of coolant flow 220 may be used to cool second temperature sensitive component 202 via thermal exchange.

Coolant flow area 212 may also include other components region 222. When traversing other components region 222, the coolant may perform thermal exchange with other components 203. For example, other components region 222 may include a main die of a GPU. As a result, the coolant flow may be used to cool the main die in addition to first temperature sensitive component 200 and second temperature sensitive component 202.

After traversing through at least first region 214 and second region 216, coolant flow 210 may be expelled from cold plate 102 via coolant outlet 208. Coolant outlet 208 may include a coolant tube and an opening through an exterior wall of cold plate 102. The coolant tube and/or opening may be of any size and/or shape through which coolant flow 210 may exit cold plate 102. For example, coolant outlet 208 may be rectangular, circular, and/or any other shape.

Turning to FIGS. 3A-3C, diagrams illustrating a cold plate (e.g., cold plate 102) in accordance with an embodiment are shown. The diagrams may include a top, partially cutaway view of cold plate 102.

As discussed above, cold plate 102 may be used as part of a thermal management system for temperature sensitive components (e.g., first temperature sensitive component 200 and second temperature sensitive component 202, refer to FIGS. 2A-2C) of a data processing system (e.g., such as data processing system 100, refer to FIG. 1). The thermal management system may include a liquid cooling system, which may utilize coolant flow 210 to cool the temperature sensitive components by traversing from coolant inlet 206, through coolant flow area 212, and out coolant outlet 208. Refer to the description of FIGS. 2A-2C for additional details.

To be used as part of the thermal management system, cold plate 102 may include first region 214 for cooling a first temperature sensitive component, and second region 216 for cooling a second temperature sensitive component. As discussed above, the first temperature sensitive component may have a first thermal dissipation requirement, and the second temperature sensitive component may have a second thermal dissipation requirement. Cold plate 102 may include any number of other regions for cooling other components, such as other components region 222. Refer to the description of FIGS. 2A-2C for additional details regarding the regions of cold plate 102.

To meet the thermal dissipation requirements of the temperature sensitive components, cold plate 102 may include first coolant flow channel 300 and second coolant flow channel 302 (e.g., 302A-302C may each illustrate an example of second coolant flow channel 302). It will be appreciated that cold plate 102 may also include other coolant flow channels. For example, cold plate 102 may include any number and/or type of coolant flow channels positioned in other components region 222.

First coolant flow channel 300 may be: (i) positioned in first region 214, and (ii) adapted to thermally manage the first temperature sensitive component. First coolant flow channel 300 may include any number of channels adapted to divide coolant flow 210 into a first portion of coolant flow 210 to allow the first portion of coolant flow 210 to traverse first region 214. In doing so, first coolant flow channel 300 may enable the first portion of coolant flow 210 to perform thermal exchange with the first temperature sensitive component to meet the first thermal dissipation requirement.

Similarly, second coolant flow channel 302 may be: (i) positioned in second region 216, and (ii) adapted to thermally manage the second temperature sensitive component. Second coolant flow channel 302 may include any number of channels adapted to divide coolant flow 210 into a second portion of coolant flow 210 to allow the second portion of coolant flow 210 to traverse second region 216. In doing so, second coolant flow channel 302 may enable the second portion of coolant flow 210 to perform thermal exchange with the second temperature sensitive component to meet the second thermal dissipation requirement.

Second region 216 may be adapted to generate a mixed flow proximate to the second temperature sensitive component to meet the second thermal dissipation requirement. The mixed flow may be generated using the second portion of coolant flow 210. To generate the mixed flow, second coolant flow channel 302 may include mixed flow generation elements. The mixed flow generation elements may generate the mixed flow by adding geometric features to and/or altering the geometry of second coolant flow channel 302.

For example, the mixed flow generation elements may include: (i) any number, type, and/or shape of posts which may be positioned to direct the second portion of the coolant flow to generate mixing in the second portion of the coolant flow, (ii) flow-altering channel walls, which may be of any thickness and/or shape adapted to generate mixing in the second portion of the coolant flow, and/or (iii) other types of mixed flow generation elements.

For example, FIG. 3A may illustrate a top view of the mixed flow generation elements for second coolant flow channel 302A including droplet-shaped posts positioned along second coolant flow channel 302A. FIG. 3B may illustrate a top view of the mixed flow generation elements for second coolant flow channel 302B including cylindrical posts positioned along second coolant flow channel 302B. FIG. 3C may illustrate a top view of the mixed flow generation elements for second coolant flow channel 302C including flow-altering channel walls of second coolant flow channel 302C. For additional details regarding the mixed flow generation elements, refer to the description of FIGS. 4A-4D.

In contrast to second coolant flow channel 302, first coolant flow channel 300 may not include mixed flow generation elements, and thus may not be adapted to generate the mixed flow. For example, first coolant flow channel 300 may: (i) allow the first portion of the coolant flow to traverse first region 214 without introducing mixing to the first portion of the coolant flow, (ii) have smooth walls, and/or (iii) otherwise not be adapted to generate the mixed flow.

The inclusion of mixed flow generation elements as part of second coolant flow channel 302 may result in a second rate of cooling of the second temperature sensitive component being higher than a first rate of cooling of the first temperature sensitive component. For example, the mixed flow may: (i) improve mixing of the coolant, (ii) reduce boundary layer resistance which may form, (iii) increase a heat transfer coefficient to improve a rate of heat transfer (e.g., the second rate of cooling), and/or (iv) otherwise increase the second rate of cooling. Consequently, the second temperature sensitive component may be cooled at a faster rate than the first temperature sensitive component. Refer to the description of FIGS. 4A-4D for additional details regarding the mixed flow.

The first rate of cooling of the first temperature sensitive component may be adapted to meet the first thermal dissipation requirement, and the second rate of cooling of the second temperature sensitive component may be adapted to meet the second thermal dissipation requirement. For example, the nominal operation temperature range (as indicated by the thermal dissipation requirements) for the first temperature sensitive component and the second temperature sensitive component may be the same. However, the first temperature sensitive component may generate less heat than the second temperature sensitive component. To maintain the nominal temperature range for desired operation of the components, the second thermal dissipation requirement may indicate that a higher rate of cooling is necessary for the second temperature sensitive component than the first thermal dissipation requirement indicates for the first temperature sensitive component. Thus, the mixed flow generated by second coolant flow channel 302 may be adapted to generate the second rate of cooling that meets the second thermal dissipation requirement, which may be lower than the first rate of cooling generated by the unmixed flow of first coolant flow channel 300 that meets the first thermal dissipation requirement.

It will be appreciated that cold plate 102 may also include other components not shown. For example, cold plate 102 may also include skived fin heat sinks, other types of heat sinks, etc.

Turning to FIG. 4A, a diagram showing an example of a second coolant flow channel (e.g., second coolant flow channel 400) in accordance with an embodiment is shown. FIG. 4A may show an isometric view of second coolant flow channel 302B shown in FIG. 3B. A top portion of the second coolant flow channel may be omitted for illustrative purposes.

Second coolant flow channel 400 may be any shape and/or dimension to allow the second portion of the coolant flow to traverse the second region, and may be positioned at any angle with respect to cold plate 102 (not shown). While FIG. 4A shows a single second coolant flow channel, it will be appreciated that any number of second coolant flow channels may be positioned within the second region of cold plate 102 to allow the second thermal dissipation requirement of the second temperature sensitive component to be met. The second coolant flow channels may include similar, different, or a combination of mixed flow generation elements.

Second coolant flow channel 400 may include first portion 401 and second portion 402. First portion 401 may be implemented with a shell, walls, and/or other structures that may be arranged to enclose an interior volume through which the second portion of the coolant flow may traverse. For example, first portion 401 may include a base portion, a top portion (not shown), and two wall portions of any size, shape, length, or thickness.

First portion 401 may be adapted to define a coolant flow path from first side 406 to second side 408. First side 406 may include a portion of second coolant flow channel 400 positioned facing towards coolant inlet 206 (not shown, refer to FIGS. 2A-3C). The second portion of the coolant flow may therefore enter second coolant flow channel 400 through first side 406. Second side 408 may include a portion of second coolant flow channel 400 positioned facing towards coolant outlet 208 (not shown, refer to FIGS. 2A-3C). The second portion of the coolant flow may therefore exit second coolant flow channel 400 through second side 408.

Second portion 402 may be adapted to generate the mixed flow using the second portion of the coolant flow. To generate the mixed flow, second portion 402 may be adapted to cause intermixing of portions of the second portion of the coolant flow to increase a rate of cooling (e.g., relative to a flow that is not mixed) so that a likelihood of the second thermal dissipation requirement being met is improved.

To cause the intermixing of the portions of the second portion of the coolant flow, second portion 402 may include mixed flow generation elements. Second portion 402 may include any number and type of mixed flow generation elements. Based on the number, type, and/or other characteristics of the mixed flow generation elements, the second rate of cooling of the second temperature sensitive component may be adapted to meet the second thermal dissipation requirement.

The mixed flow generation elements may include posts 404. Posts 404 may be positioned with respect to first portion 401 to direct the coolant flow path. Directing the coolant flow path may allow portions of the second portion of the coolant flow to intermix along a direction of travel of the second portion of the coolant flow (e.g., from first side 406 to second side 408). The intermixing of the portions may establish the mixed flow, and thus, may increase the rate of cooling. Posts 404 may be implemented using rods and/or other types of features projecting from a base, top, and/or walls of first portion 401. Posts 404 may be of any size, shape, and quantity.

While illustrated in FIG. 4A as cylindrical features projecting from the bottom of first portion 401, it will be appreciated that posts 404 may project from any portion of first portion 401 and may be of any shape, width, and/or length without departing from embodiments disclosed herein.

The mixed flow generation elements may also include flow-altering channel walls adapted to cause the intermixing of the portions of the second portion of the coolant flow. Refer to the description of FIG. 4D for additional details.

Turning to FIGS. 4B-4D, diagrams showing examples of a second coolant flow channel (e.g., second coolant flow channel 400A-C) in accordance with an embodiment are shown. FIG. 4B may show a top view of second coolant flow channel 302B shown in FIG. 3B and/or second coolant flow channel 400 shown in FIG. 4A. FIG. 4C may show a top view of second coolant flow channel 302A shown in FIG. 3A. FIG. 4D may show a top view of second coolant flow channel 302C shown in FIG. 3C. A top portion of the second coolant flow channel may be omitted for illustrative purposes.

Second coolant flow channels 400A-400C may include first side 406, second side 408, first portion 401, and second portion 402. For additional details regarding these components, refer to the description of FIG. 4A.

Second coolant flow channels 400A-400C may include mixed flow generation elements to generate a mixed flow used to cool the second temperature sensitive component. The mixed flow may follow coolant flow path 410.

In a first example, the mixed flow generation elements included as part of second coolant flow channel 400A shown in FIG. 4B may include posts 404A. Posts 404A may include cylindrical features projecting from first portion 401.

In a second example, the mixed flow generation elements included as part of second coolant flow channel 400B shown in FIG. 4C may include posts 404B. Posts 404B may include droplet-shaped features projecting from first portion 401.

In a third example, the mixed flow generation elements included as part of second coolant flow channel 400C shown in FIG. 4D may include flow-altering channel walls 412. Flow-altering channel walls 412 may be positioned with respect to first portion 401 to direct coolant flow path 410. Directing coolant flow path 410 may allow portions of the second portion of the coolant flow to intermix along a direction of travel of the second portion of the coolant flow. The intermixing of the portions may establish the mixed flow, and thus, may increase the rate of cooling (e.g., relative to a flow that is not mixed). Flow-altering channel walls 412 may divide the second portion of the coolant flow into portions (shown in FIG. 4D as being divided into two portions), and/or may not further divide the second portion of the coolant flow. Flow-altering channel walls 412 may be of any shape, width, height, length, and/or quantity.

The mixed flow generated by the mixed flow generation elements may have a serpentine flow pattern, as illustrated by coolant flow path 410. The serpentine flow path may include a flow path that follows a winding, snake-like path, rather than, for example, a straight line. While described with respect to the mixed flow having a serpentine flow pattern, it will be appreciated that any other type of mixed flow pattern may be generated, such as a swirling pattern, etc.

Thus, embodiments disclosed herein may address, among others, the technical challenge of thermal management of hardware components of a data processing system that may generate heat during operation. Embodiments disclosed herein may do so using a cold plate. The cold plate may include channels adapted to generate a mixed flow to meet thermal dissipation requirements of the hardware components. To do so, the channels may include mixed flow generation elements, such as posts, flow-altering channel walls, etc. Doing so may allow rates of cooling in various regions of the cold plate to be adapted to meet thermal dissipation requirements of temperature sensitive components associated with the regions. As a result, computer-implemented services may be provided by the data processing system as desired.

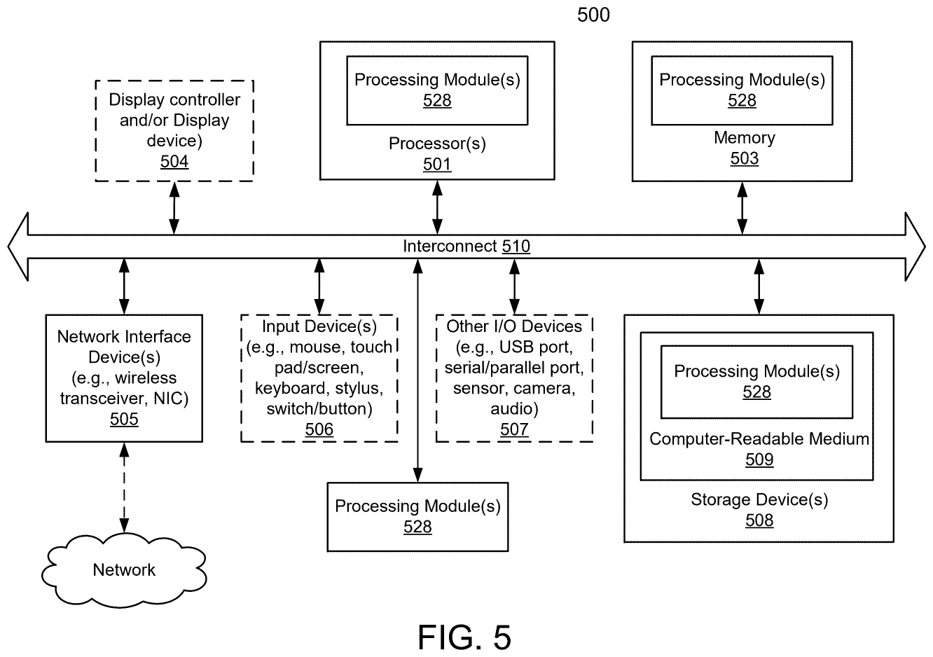

Any of the components illustrated in FIGS. 1-4D may be implemented with one or more computing devices. Turning to FIG. 5, a block diagram illustrating an example of a data processing system (e.g., a computing device) in accordance with an embodiment is shown. For example, system 500 may represent any of data processing systems described above performing any of the processes or methods described above. System 500 can include many different components. These components can be implemented as integrated circuits (ICs), portions thereof, discrete electronic devices, or other modules adapted to a circuit board such as a motherboard or add-in card of the computer system, or as components otherwise incorporated within a chassis of the computer system. Note also that system 500 is intended to show a high level view of many components of the computer system. However, it is to be understood that additional components may be present in certain implementations and furthermore, different arrangement of the components shown may occur in other implementations. System 500 may represent a desktop, a laptop, a tablet, a server, a mobile phone, a media player, a personal digital assistant (PDA), a personal communicator, a gaming device, a network router or hub, a wireless access point (AP) or repeater, a set-top box, or a combination thereof. Further, while only a single machine or system is illustrated, the term “machine” or “system” shall also be taken to include any collection of machines or systems that individually or jointly execute a set (or multiple sets) of instructions to perform any one or more of the methodologies discussed herein.

In one embodiment, system 500 includes processor 501, memory 503, and devices 505-507 via a bus or an interconnect 510. Processor 501 may represent a single processor or multiple processors with a single processor core or multiple processor cores included therein. Processor 501 may represent one or more general-purpose processors such as a microprocessor, a central processing unit (CPU), or the like. More particularly, processor 501 may be a complex instruction set computing (CISC) microprocessor, reduced instruction set computing (RISC) microprocessor, very long instruction word (VLIW) microprocessor, or processor implementing other instruction sets, or processors implementing a combination of instruction sets. Processor 501 may also be one or more special-purpose processors such as an application specific integrated circuit (ASIC), a cellular or baseband processor, a field programmable gate array (FPGA), a digital signal processor (DSP), a network processor, a graphics processor, a network processor, a communications processor, a cryptographic processor, a co-processor, an embedded processor, or any other type of logic capable of processing instructions.

Processor 501, which may be a low power multi-core processor socket such as an ultra-low voltage processor, may act as a main processing unit and central hub for communication with the various components of the system. Such processor can be implemented as a system on chip (SoC). Processor 501 is configured to execute instructions for performing the operations discussed herein. System 500 may further include a graphics interface that communicates with optional graphics subsystem 504, which may include a display controller, a graphics processor, and/or a display device.

Processor 501 may communicate with memory 503, which in one embodiment can be implemented via multiple memory devices to provide for a given amount of system memory. Memory 503 may include one or more volatile storage (or memory) devices such as random access memory (RAM), dynamic RAM (DRAM), synchronous DRAM (SDRAM), static RAM (SRAM), or other types of storage devices. Memory 503 may store information including sequences of instructions that are executed by processor 501, or any other device. For example, executable code and/or data of a variety of operating systems, device drivers, firmware (e.g., input output basic system or BIOS), and/or applications can be loaded in memory 503 and executed by processor 501. An operating system can be any kind of operating systems, such as, for example, Windows® operating system from Microsoft®, Mac OS®/iOS® from Apple, Android® from Google®, Linux®, Unix®, or other real-time or embedded operating systems such as VxWorks.

System 500 may further include IO devices such as devices (e.g., 505, 506, 507, 508) including network interface device(s) 505, optional input device(s) 506, and other optional IO device(s) 507. Network interface device(s) 505 may include a wireless transceiver and/or a network interface card (NIC). The wireless transceiver may be a WiFi transceiver, an infrared transceiver, a Bluetooth transceiver, a WiMax transceiver, a wireless cellular telephony transceiver, a satellite transceiver (e.g., a global positioning system (GPS) transceiver), or other radio frequency (RF) transceivers, or a combination thereof. The NIC may be an Ethernet card.

Input device(s) 506 may include a mouse, a touch pad, a touch sensitive screen (which may be integrated with a display device of optional graphics subsystem 504), a pointer device such as a stylus, and/or a keyboard (e.g., physical keyboard or a virtual keyboard displayed as part of a touch sensitive screen). For example, input device(s) 506 may include a touch screen controller coupled to a touch screen. The touch screen and touch screen controller can, for example, detect contact and movement or break thereof using any of a plurality of touch sensitivity technologies, including but not limited to capacitive, resistive, infrared, and surface acoustic wave technologies, as well as other proximity sensor arrays or other elements for determining one or more points of contact with the touch screen.

IO devices 507 may include an audio device. An audio device may include a speaker and/or a microphone to facilitate voice-enabled functions, such as voice recognition, voice replication, digital recording, and/or telephony functions. Other IO devices 507 may further include universal serial bus (USB) port(s), parallel port(s), serial port(s), a printer, a network interface, a bus bridge (e.g., a PCI-PCI bridge), sensor(s) (e.g., a motion sensor such as an accelerometer, gyroscope, a magnetometer, a light sensor, compass, a proximity sensor, etc.), or a combination thereof. IO device(s) 507 may further include an imaging processing subsystem (e.g., a camera), which may include an optical sensor, such as a charged coupled device (CCD) or a complementary metal-oxide semiconductor (CMOS) optical sensor, utilized to facilitate camera functions, such as recording photographs and video clips. Certain sensors may be coupled to interconnect 510 via a sensor hub (not shown), while other devices such as a keyboard or thermal sensor may be controlled by an embedded controller (not shown), dependent upon the specific configuration or design of system 500.

To provide for persistent storage of information such as data, applications, one or more operating systems and so forth, a mass storage (not shown) may also couple to processor 501. In various embodiments, to enable a thinner and lighter system design as well as to improve system responsiveness, this mass storage may be implemented via a solid state device (SSD). However, in other embodiments, the mass storage may primarily be implemented using a hard disk drive (HDD) with a smaller amount of SSD storage to act as an SSD cache to enable non-volatile storage of context state and other such information during power down events so that a fast power up can occur on re-initiation of system activities. Also a flash device may be coupled to processor 501, e.g., via a serial peripheral interface (SPI). This flash device may provide for non-volatile storage of system software, including a basic input/output software (BIOS) as well as other firmware of the system.

Storage device 508 may include computer-readable storage medium 509 (also known as a machine-readable storage medium or a computer-readable medium) on which is stored one or more sets of instructions or software (e.g., processing module, unit, and/or processing module/unit/logic 528) embodying any one or more of the methodologies or functions described herein. Processing module/unit/logic 528 may represent any of the components described above. Processing module/unit/logic 528 may also reside, completely or at least partially, within memory 503 and/or within processor 501 during execution thereof by system 500, memory 503 and processor 501 also constituting machine-accessible storage media. Processing module/unit/logic 528 may further be transmitted or received over a network via network interface device(s) 505.

Computer-readable storage medium 509 may also be used to store some software functionalities described above persistently. While computer-readable storage medium 509 is shown in an exemplary embodiment to be a single medium, the term “computer-readable storage medium” should be taken to include a single medium or multiple media (e.g., a centralized or distributed database, and/or associated caches and servers) that store the one or more sets of instructions. The terms “computer-readable storage medium” shall also be taken to include any medium that is capable of storing or encoding a set of instructions for execution by the machine and that cause the machine to perform any one or more of the methodologies of embodiments disclosed herein. The term “computer-readable storage medium” shall accordingly be taken to include, but not be limited to, solid-state memories, and optical and magnetic media, or any other non-transitory machine-readable medium.

Processing module/unit/logic 528, components and other features described herein can be implemented as discrete hardware components or integrated in the functionality of hardware components such as ASICS, FPGAs, DSPs or similar devices. In addition, processing module/unit/logic 528 can be implemented as firmware or functional circuitry within hardware devices. Further, processing module/unit/logic 528 can be implemented in any combination hardware devices and software components.

Note that while system 500 is illustrated with various components of a data processing system, it is not intended to represent any particular architecture or manner of interconnecting the components; as such details are not germane to embodiments disclosed herein. It will also be appreciated that network computers, handheld computers, mobile phones, servers, and/or other data processing systems which have fewer components or perhaps more components may also be used with embodiments disclosed herein.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities.

It should be borne in mind, however, that all of these and similar terms are to be associated with the appropriate physical quantities and are merely convenient labels applied to these quantities. Unless specifically stated otherwise as apparent from the above discussion, it is appreciated that throughout the description, discussions utilizing terms such as those set forth in the claims below, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Embodiments disclosed herein also relate to an apparatus for performing the operations herein. Such a computer program is stored in a non-transitory computer readable medium. A non-transitory machine-readable medium includes any mechanism for storing information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices).

The processes or methods depicted in the preceding figures may be performed by processing logic that comprises hardware (e.g. circuitry, dedicated logic, etc.), software (e.g., embodied on a non-transitory computer readable medium), or a combination of both. Although the processes or methods are described above in terms of some sequential operations, it should be appreciated that some of the operations described may be performed in a different order. Moreover, some operations may be performed in parallel rather than sequentially.

Embodiments disclosed herein are not described with reference to any particular programming language. It will be appreciated that a variety of programming languages may be used to implement the teachings of embodiments disclosed herein.

In the foregoing specification, embodiments have been described with reference to specific exemplary embodiments thereof. It will be evident that various modifications may be made thereto without departing from the broader spirit and scope of the embodiments disclosed herein as set forth in the following claims. The specification and drawings are, accordingly, to be regarded in an illustrative sense rather than a restrictive sense.

What is claimed is:

1. A data processing system, comprising:
a first temperature sensitive component having a first thermal dissipation requirement;
a second temperature sensitive component having a second thermal dissipation requirement;
a chassis for housing the first temperature sensitive component and the second temperature sensitive component; and
a cold plate, comprising:
a first region for cooling the first temperature sensitive component; and
a second region for cooling the second temperature sensitive component, the second region being adapted to generate a mixed flow proximate to the second temperature sensitive component to meet the second thermal dissipation requirement.

2. The data processing system of claim 1, wherein the cold plate further comprises:
a first coolant flow channel that is:
positioned in the first region, and
adapted to thermally manage the first temperature sensitive component; and
a second coolant flow channel that is:
positioned in the second region, and
adapted to thermally manage the second temperature sensitive component.

3. The data processing system of claim 2, wherein the cold plate is adapted to:
receive a coolant flow;
divide the coolant flow into a first portion of the coolant flow using the first coolant flow channel, and a second portion of the coolant flow using the second coolant flow channel; and
expel the coolant flow from the cold plate after the coolant flow traverses through the first region and the second region.

4. The data processing system of claim 3, wherein the second coolant flow channel is adapted to generate the mixed flow using the second portion of the coolant flow, and the first coolant flow channel is not adapted to generate the mixed flow.

5. The data processing system of claim 4, wherein the second coolant flow channel comprises:
a first portion of the second coolant flow channel adapted to:
define a coolant flow path from a first side of the second region to a second side of the second region; and
a second portion of the second coolant flow channel adapted to generate the mixed flow.

6. The data processing system of claim 5, wherein the second portion of the second coolant flow channel comprises:
posts positioned with respect to the first portion to direct the coolant flow path to intermix portions of the second portion of the coolant flow along a direction of travel of the second portion of the coolant flow, the intermixing of the portions establishing the mixed flow.

7. The data processing system of claim 5, wherein the second portion of the second coolant flow channel comprises:
flow-altering channel walls positioned with respect to the first portion to direct the coolant flow path to intermix portions of the second portion of the coolant flow along a direction of travel of the second portion of the coolant flow, the intermixing of the portions establishing the mixed flow.

8. The data processing system of claim 5, wherein the second portion of the second coolant flow channel is adapted to cause intermixing of portions of the second portion of the coolant flow to increase a rate of cooling so that a likelihood of the second thermal dissipation requirement being met is improved.

9. The data processing system of claim 1, wherein a first rate of cooling of the first temperature sensitive component is lower than a second rate of cooling of the second temperature sensitive component.

10. The data processing system of claim 9, wherein the first rate of cooling is adapted to meet the first thermal dissipation requirement, and the second rate of cooling is adapted to meet the second thermal dissipation requirement.

11. The data processing system of claim 1, wherein the mixed flow has a serpentine flow pattern.

12. A chassis for a data processing system, the chassis comprising:
an enclosure for housing:
a first temperature sensitive component having a first thermal dissipation requirement, and
a second temperature sensitive component having a second thermal dissipation requirement; and
a cold plate, comprising:
a first region for cooling the first temperature sensitive component; and
a second region for cooling the second temperature sensitive component, the second region being adapted to generate a mixed flow proximate to the second temperature sensitive component to meet the second thermal dissipation requirement.

13. The chassis of claim 12, wherein the cold plate further comprises:
a first coolant flow channel that is:
positioned in the first region, and
adapted to thermally manage the first temperature sensitive component; and
a second coolant flow channel that is:
positioned in the second region, and
adapted to thermally manage the second temperature sensitive component.

14. The chassis of claim 13, wherein the cold plate is adapted to:
receive a coolant flow;
divide the coolant flow into a first portion of the coolant flow using the first coolant flow channel, and a second portion of the coolant flow using the second coolant flow channel; and
expel the coolant flow from the cold plate after the coolant flow traverses through the first region and the second region.

15. The chassis of claim 14, wherein the second coolant flow channel is adapted to generate the mixed flow using the second portion of the coolant flow, and the first coolant flow channel is not adapted to generate the mixed flow.

16. A cold plate for a chassis of a data processing system, the cold plate comprising:
a first region adapted to cool a first temperature sensitive component, the first temperature sensitive component having a first thermal dissipation requirement; and
a second region adapted to cool a second temperature sensitive component, the second temperature sensitive component having a second thermal dissipation requirement, and the second region being adapted to generate a mixed flow proximate to the second temperature sensitive component to meet the second thermal dissipation requirement.

17. The cold plate of claim 16, wherein the cold plate further comprises:
a first coolant flow channel that is:
positioned in the first region, and
adapted to thermally manage the first temperature sensitive component; and
a second coolant flow channel that is:
positioned in the second region, and
adapted to thermally manage the second temperature sensitive component.

18. The cold plate of claim 17, wherein the cold plate is adapted to:
receive a coolant flow;
divide the coolant flow into a first portion of the coolant flow using the first coolant flow channel, and a second portion of the coolant flow using the second coolant flow channel; and
expel the coolant flow from the cold plate after the coolant flow traverses through the first region and the second region.

19. The cold plate of claim 18, wherein the second coolant flow channel is adapted to generate the mixed flow using the second portion of the coolant flow, and the first coolant flow channel is not adapted to generate the mixed flow.

20. The cold plate of claim 18, wherein the second coolant flow channel comprises:
a first portion of the second coolant flow channel adapted to:
define a coolant flow path from a first side of the second region to a second side of the second region; and
a second portion of the second coolant flow channel adapted to generate the mixed flow.
